(19) United States
(12) Patent Application Publication
(10) Pub. No.: US 2004/0037149 A1
(43) Pub. Date: Feb. 26, 2004

(54) Semiconductor memory device capable of normal transition to test mode

(75) Inventor: Goro Hayakawa, Hyogo (JP)

Correspondence Address: McDermott, Will & Emery, 600 13th Street, N.W., Washington, DC, 20005-3096, US

(73) Assignee: MITSUBISHI DENKI KABUSHIKI KAISHA

(21) Appl. No.: 10/357,211

(22) Filed: Feb. 4, 2003

(30) Foreign Application Priority Data
Aug. 21, 2002 (JP) 2002-240684(P)

(51) Int. Cl. G11C 5/00

(52) U.S. Cl. 365/226

(57) ABSTRACT

A clamp circuit and a high-voltage detection circuit are supplied with voltages from different power-supplies respectively. At a normal mode, the clamp circuit and the high-voltage detection circuit are supplied with a voltage of almost the same voltage level. At transition to the test mode, only the voltage supplied to the clamp circuit is increased to activate the high-voltage detection circuit.

### BACKGROUND OF THE INVENTION

1. Field of the Invention

The present invention relates to a semiconductor memory device, and more particularly, to a semiconductor memory device having a test mode.

2. Description of the Background Art

A semiconductor device, e.g. DRAM (Dynamic Random Access Memory), includes a built-in test circuit that performs a multi-bit test, i.e. one of a shipment test, in addition to other circuits performing normal operation such as storing or reading of data. In order to prevent such a test circuit from accidentally operating at the time of normal operation, the test circuit is so configured as to operate in response to e.g. a prescribed address signal and a result of determination of a voltage higher than a power-supply voltage VCC by a high voltage detection circuit within the DRAM. It is noted that, for example, a power-supply node supplying power-supply voltage VCC is also simply referred to as power-supply voltage VCC in the present specification.

As DRAMs have recently been increased in speed, the switching operation thereof is also becoming faster. This causes overshoot and undershoot of input signals if a DRAM operates at a high frequency. Such overshoot and undershoot may lead to e.g. erroneous reading of data from the DRAM. In order to avoid such problems associated with overshoot and undershoot, a clamp circuit is generally provided at each input terminal in the DRAM.

The clamp circuit has a function of maintaining a voltage of an input terminal so as not to exceed a voltage obtained by adding a prescribed voltage to power-supply voltage VCC, and not to be lower than a voltage obtained by subtracting a prescribed voltage from ground voltage VSS, even if a voltage of an input signal to an input terminal is higher than power-supply voltage VCC or lower than ground voltage VSS. It is noted that, in the present specification, a normal operation mode in which a semiconductor memory device performs reading and writing of data is also referred to as a normal mode, whereas an operation mode in which it performs a multi-bit test or the like is also referred to as a test mode.

FIG. 8 shows a configuration of a conventional semiconductor memory device 104 that has a function of detecting a high voltage and that is capable of transition from the normal mode to the test mode. As shown in FIG. 8, semiconductor memory device 104 includes a terminal 17, an anti-surge resistance 15, an input buffer 11, a high-voltage detection circuit 12 and a mode switching circuit 40. Terminal 17 generically represents a plurality of terminals provided in correspondence to address signals EXTADD<0:n>, respectively. Terminal 17 receives inputs of address signals EXTADD<0:n>, respectively.

Here, EXTADD<0:n> is a generic representation of EXTADD<0> to EXTADD<n>. It is noted that a similar representation is used to generically indicate a plurality of bit signals in the present specification. A high-voltage state (e.g. power-supply voltage VCC) and a low-voltage state (e.g. ground voltage VSS) of a signal, data and the like in binary are also referred to as a logic high or an “H” level and a logic low or an “L” level, respectively.

Resistance 15 generically represents a plurality of resistances provided in correspondence to address signals EXTADD<0:n>, respectively. Resistance 15 is connected to terminal 17, respectively. Further, address signals EXTADD<0:n> come to be signals INTADD<0:n> via resistance 15. Moreover, resistance 15 is set to have a very low resistance value such that the voltage of signals INTADD<0:n> is almost equal to the voltage of address signals EXTADD<0:n>.

Input buffer 11 generically represents a plurality of input buffers provided in correspondence to signals INTADD<0:n>, respectively. Input buffer 11 sets output signals ADD<0:n> to the H or L level in accordance with the voltage levels of signals INTADD<0:n>. High-voltage detection circuit 12 receives an input of only one signal INTADD<0> of signals INTADD<0:n>. Moreover, high-voltage detection circuit 12 is supplied with power-supply voltage VCC, and sets an output signal SVIH to the H level if the voltage of signal INTADD<0> is a prescribed voltage higher than power-supply voltage VCC.

Mode switching circuit 40 is activated by signal SVIH of the H level and a prescribed combination of H and L levels of signals ADD<1:m>, i.e. at least a part of signals ADD<0:n> (hereinafter, m satisfies 1≦m≦n in the present specification), to change the operation mode of semiconductor memory device 104 from the normal mode to the test mode.

An example of operation of semiconductor memory device 104 that is switched from the normal mode to the test mode will now be described with reference to FIG. 8. Here, by way of example, power-supply voltage VCC is set to 3.3V and a voltage level at which the high-voltage detection circuit 12 is activated is set to 5V.

When address signal EXTADD<0> of 5V is input into terminal 17 of semiconductor memory device 104, input buffer 11 sets signal ADD<0> to the H level. Moreover, signal INTADD<0> also has 5V, high-voltage detection circuit 12 sets signal SVIH to the H level. Further, when EXTADD<1:m> of address signals EXTADD<0:n> are input into terminal 17 with a prescribed combination of H and L levels, signals ADD<1:m> corresponding to the input address signals EXTADD<1:m> also have the prescribed combination of H and L levels, activating mode switching circuit 40. As a result, mode switching circuit 40 changes the mode of semiconductor memory device 104 from the normal mode to the test mode.

However, semiconductor memory device 104 operates at a very high frequency, which may cause overshoot and undershoot if the speed of switching address signal EXTADD<0> between H and L levels increases, possibly resulting in erroneous reading of an address signal.

FIG. 9 shows a configuration of a conventional semiconductor memory device 105 provided with a countermeasure against overshoot and undershoot. Semiconductor memory device 105 is different from semiconductor memory device 104 in that a diode 13 is provided between power-supply voltage VCC and a connection node of resistance 15 to input buffer 11, that a diode 14 is provided between a connection node of resistance 15 to input buffer 11 and ground voltage VSS, and that high-voltage detection circuit 12 and mode switching circuit 40 are eliminated. The other parts are configured as in semiconductor memory device 104, so that detailed description thereof will not be repeated. An anode of diode 13 and a cathode of diode 14 are connected to the connection node of resistance 15 to input buffer 11.

Each of diodes 13 and 14 is a generic representation of a plurality of diodes provided in correspondence to signals INTADD<0:n>, respectively. Diode 13 electrically connects the connection node of resistance 15 and input buffer 11 and power-supply voltage VCC when the voltage of the connection node of resistance 15 to input buffer 11 exceeds power-supply voltage VCC by at least a prescribed level. Diode 14 electrically connects the connection node of resistance 15 to input buffer 11 with ground voltage VSS, when the voltage of the connection node of resistance 15 to input buffer 11 becomes lower than ground voltage VSS by at least a prescribed level.

An example of operation of semiconductor memory device 105 will now be described with reference to FIG. 9. It is assumed that semiconductor memory device 105 operates at a very high frequency and that switching between H and L levels are performed after the voltage of address signal EXTADD<0> is set to the H or L level and before the voltage becomes constant. Here, by way of example, power-supply voltage VCC is set to 3.3V, ground voltage VSS is 0V, and a voltage drop level by diodes 13 and 14 is 0.6V. A threshold voltage at which input buffer 11 determines for H or L level is assumed to be 1.4V.

It is assumed that address signal EXTADD<0> is input into semiconductor memory device 105, sequentially having L and H levels, and momentarily varies an amplitude of signal INTADD<0> in the range between 1.3V and 5V. This is the phenomenon called overshoot. If no diode 13 is provided here, when signal INTADD<0> comes to have 1.3 V, signal INTADD<0> that is supposed to be determined as the H level may possibly be determined as the L level by input buffer 11. Diode 13, however, functions to maintain the voltage of signal INTADD<0> at 3.9V even if it exceeds 3.9V. Thus, signal INTADD<0> will not be determined as the L level by input buffer 11.

It is assumed that address signal EXTADD<0> is input into semiconductor memory device 105, sequentially having H and L levels, and momentarily varies the amplitude of signal INTADD<0> in the range between −2 and 1.5. This is the phenomenon called undershoot. If no diode 14 is provided here, when signal INTADD<0> comes to have 1.5V, signal INTADD that is supposed to be determined as the L level may possibly be determined as the H level by input buffer 11. Diode 14, however, functions to maintain the voltage of signal INTADD<0> at −0.6V even if it becomes lower than −0.6V. Thus, signal INTADD<0> will not be determined as the H level by input buffer 11.

FIG. 10 is an operation waveform for the case where diodes 13 and 14 are provided between resistance 15 and input buffer 11 by way of experiment, for preventing overshoot and undershoot of an input signal, in semiconductor memory device 104 having a high-voltage detection function and capable of transition from the normal mode to the test mode, as in semiconductor memory device 105. Here, by way of example, power-supply voltage VCC is set to 3.3V, ground voltage VSS is 0V, and the voltage level at which the high-voltage detection circuit 12 is activated is 5V.

Referring to FIGS. 8, 9 and 10, at time t1, when address signal EXTADD<0> of 5V for transition to the test mode is input into the experimental semiconductor memory device above, the voltage of signal EXTADD<0> is clamped at 3.9V by diode 13. This sets signal INTADD <0> to 3.9V, not activating high-voltage detection circuit 12, so that output signal SVIH remains at the L level. As a result, the experimental semiconductor memory device cannot be switched to the test mode.

As described above, even if conventional semiconductor memory device 104 that has a high-voltage detection function and that can be switched from the normal mode to the test mode is provided with diodes 13 and 14 as in semiconductor memory device 105 in order to prevent overshoot and undershoot of input signals, transition to the test mode cannot be normally performed.

### SUMMARY OF THE INVENTION

An object of the present invention is to provide a semiconductor memory device that can prevent overshoot and undershoot of an input signal at a normal mode, and that can perform normal transition to a test mode.

According to an aspect of the present invention, a semiconductor memory device having a normal mode and a test mode as operation modes includes a plurality of terminals capable of receiving inputs of external voltage signals, a high-voltage detection circuit supplied with an operation voltage from a first power-supply node and detecting that a first prescribed voltage higher than a voltage of the first power-supply node is applied to one of the plurality of terminals to produce an instruction for mode transition, a first clamp circuit provided between a second power-supply node and the one terminal and electrically connecting the one terminal to the second power-supply node if a voltage of the one terminal is lower than a voltage of the second power-supply node by a prescribed level, a second clamp circuit provided between a third power-supply node and the one terminal and electrically connecting the one terminal to the third power-supply node if the voltage of the one terminal is higher than a voltage of the third power-supply node by a prescribed level, and a mode switching circuit changing the operation mode from the normal mode to the test mode in response to a combination of voltage levels of at least a part of the plurality of terminals and to the instruction for mode transition. The first and third power-supply nodes have voltages higher than the voltage of the second power-supply node. The first and third power-supply nodes are supplied with a voltage of a same level at the normal mode. The third power-supply node is supplied with a voltage higher than the voltage of the first power-supply node corresponding to the first prescribed voltage at transition to the test mode.

Thus, a primary advantage of the present invention is that a semiconductor memory device can be realized that can prevent overshoot and undershoot of an input signal at the normal mode while normally performing transition to the test mode, by providing different power supplies for supplying voltages to the clamp circuit and the high-voltage detection circuit respectively and by increasing only the voltage supplied to the clamp circuit at transition to the test mode to activate the high-voltage detection circuit.

According to another aspect of the present invention, a semiconductor memory device having a normal mode and a test mode as operation modes includes a plurality of terminals capable of receiving inputs of external voltage signals, a high-voltage detection circuit supplied with an operation voltage from a first power-supply node and producing an instruction for mode transition in response to a first prescribed voltage higher than a voltage of the first power-supply node being applied to one of the plurality of terminals, a mode switching circuit changing the operation mode from the normal mode to the test mode in response to a combination of voltage levels of at least a part of the plurality of terminals and to the instruction for mode transition, a data line connected to the one terminal, and a data output circuit sending output data to the data line. The data output circuit includes first and second transistors provided between the data line and second and third power-supply nodes, respectively, and complementarily turned on at data output in accordance with the output data. Substrate regions of the first and second transistors are electrically connected to the second and third power-supply nodes respectively. The first and second power-supply nodes have voltages higher than a voltage of the third power-supply node. The first and second power-supply nodes are supplied with a voltage of a same level at the normal mode. The second power-supply node is supplied with a voltage higher than the voltage of the first power-supply node corresponding to the first prescribed voltage at transition to the test mode.

Thus, the semiconductor memory device according to the present invention can reduce the circuit area and cost without the need for further provision of a clamp circuit, by making a transistor in the data output circuit operate as a clamp circuit.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the configuration of a semiconductor memory device according to the first embodiment of the present invention;

FIG. 2 is an operation waveform illustrating the operation at transition from the normal mode to the test mode in a semiconductor memory device;

FIG. 3 is a block diagram showing the configuration of a semiconductor memory device according to the second embodiment of the present invention;

FIGS. 4 and 5 are operation waveforms illustrating the operation at transition from the normal mode to the test mode in a semiconductor device;

FIG. 6 is a block diagram showing the configuration of a semiconductor memory device according to the third embodiment of the present invention;

FIG. 7 is an operation waveform illustrating the operation at transition from the normal mode to the test mode in a semiconductor memory device;

FIG. 8 is a block diagram showing the configuration of the conventional semiconductor memory device having a high-voltage detection function and capable of performing transition from the normal mode to the test mode;

FIG. 9 is a block diagram showing the conventional semiconductor memory device provided with a countermeasure against overshoot and undershoot; and

FIG. 10 is an operation waveform in an experimental semiconductor memory device.

### DESCRIPTION OF THE PREFERRED EMBODIMENTS

Embodiments of the present invention will be described below with reference to the drawings. It is noted that the same or corresponding portions are denoted by the same reference characters.

First Embodiment

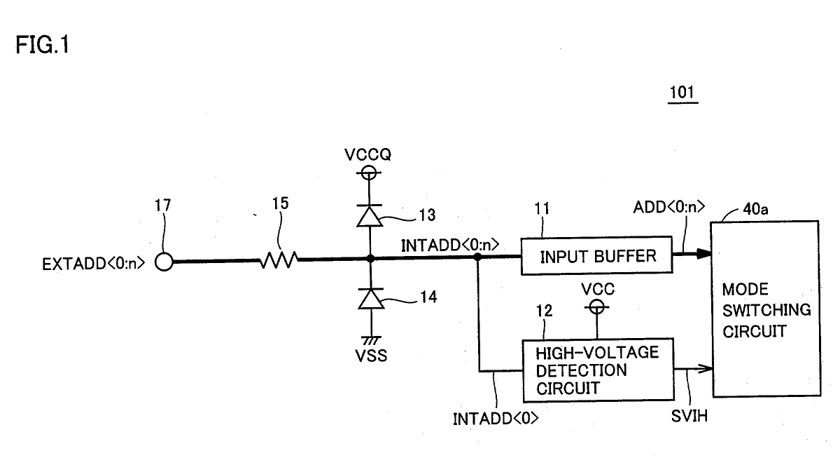

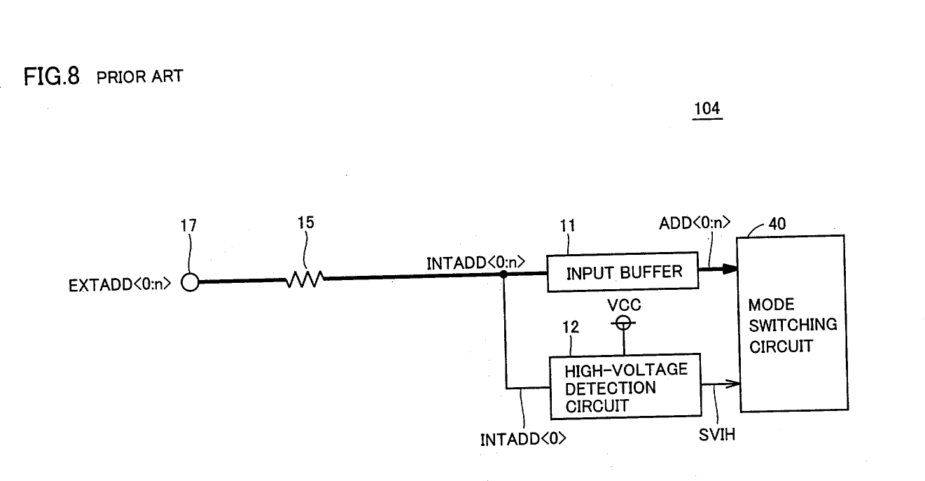

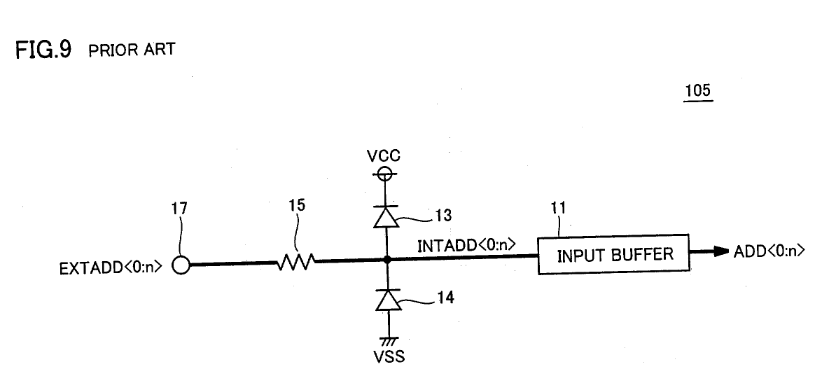

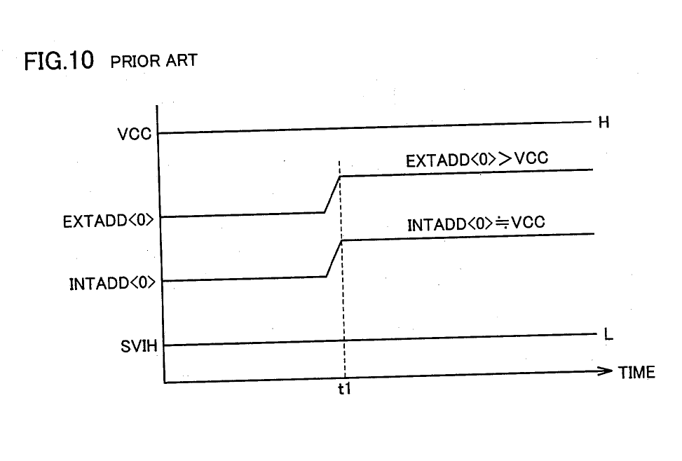

Referring to FIG. 1, a semiconductor memory device 101 according to the first embodiment of the present invention is different from conventional semiconductor memory device 104 shown in FIG. 8 in that it includes a mode switching circuit 40a in place of mode switching circuit 40, and that it further includes diodes 13 and 14 provided as a clamp circuit. The other parts are configured as in semiconductor memory device 104 shown in FIG. 8, so that detailed description thereof will not be repeated.

Mode switching circuit 40a is activated by a prescribed combination of H and L levels of ADD<1:m>, i.e. at least a part of signals ADD<0:n>, and by signal SVIH of the H level, to change the mode of semiconductor memory device 101 from the normal mode to the test mode.

Diode 13 is arranged between a power-supply voltage VCCQ and a connection node of resistance 15 to input buffer 11. Diode 14 is provided between the connection node of resistance 15 to input buffer 11 and ground voltage VSS.

The operation of semiconductor memory device 101 for preventing overshoot and undershoot at the normal mode is similar to that of semiconductor memory device 105, so that detailed description thereof will not be repeated.

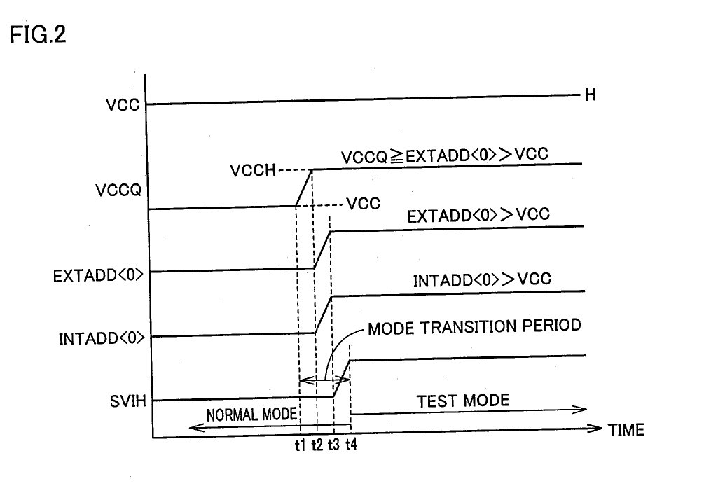

FIG. 2 is an operation waveform illustrating the operation at transition from the normal mode to the test mode in semiconductor memory device 101. The period from time t1 to t4 is a mode transition period for semiconductor memory device 101 to be switched from the normal mode to the test mode. Power-supply voltage VCCQ supplies the same voltage as power-supply voltage VCC before the mode transition period, whereas it supplies a voltage VCCH at which a high-voltage detection circuit is activated after time t2 in the mode transition period. Here, by way of example, power-supply voltage VCC is set to 3.3V, ground voltage VSS is 0V, a voltage level at which high-voltage detection circuit 12 is activated is 5V, a voltage drop level by diodes 13 and 14 is 0.6V, and voltage VCCH is 5V.

Referring to FIGS. 1 and 2, in semiconductor memory device 101, power-supply voltage VCCQ supplies voltage VCCH at time t2. Subsequently, when address signal EXTADD<0> of 5V for transition to the test mode is input into terminal 17 at time t3, address signal EXTADD<0> is set to signal INTADD<0> of 5V.

High-voltage detection circuit 12 is activated when signal INTADD<0> of 5V is input, and sets output signal SVIH to the H level. If EXTADD<1:m> of address signals EXTADD<0:n> are input into terminal 17 with a prescribed combination of H and L levels, signals ADD<1:m> also have a prescribed combination of H and L levels, activating mode switching circuit 40a. As a result, mode switching circuit 40a changes the mode of semiconductor memory device 101 from the normal mode to the test mode at time t4.

Accordingly, semiconductor memory device 101 can prevent overshoot and undershoot of an input signal at the normal mode while normally performing transition operation to the test mode.

Second Embodiment

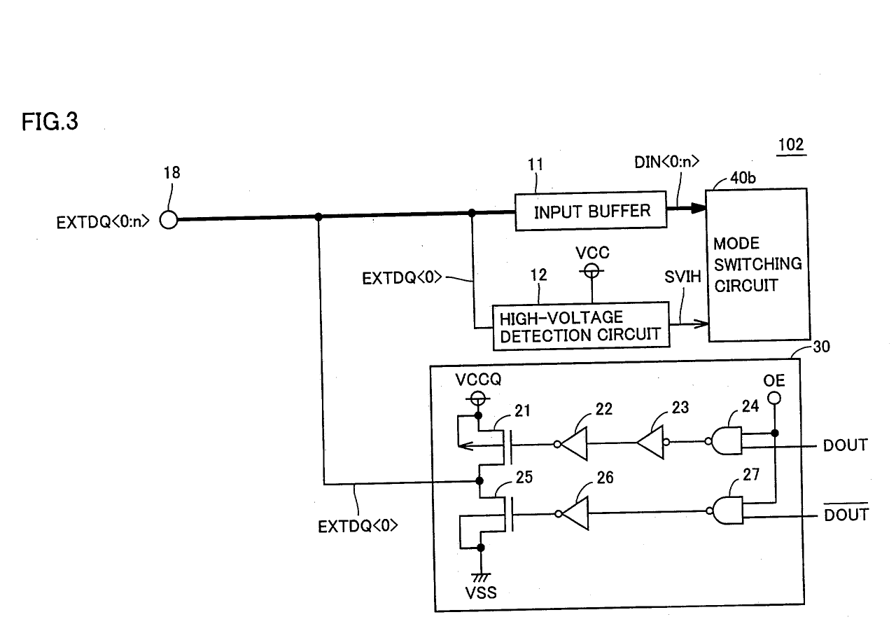

Referring to FIG. 3, a semiconductor memory device 102 according to the second embodiment is different from semiconductor memory device 101 shown in FIG. 1 in that it includes a terminal 18 in place of terminal 17, and a mode switching circuit 40b in place of mode switching circuit 40a, that it further includes an output buffer 30, and that diodes 13, 14 and resistance 15 are eliminated.

In addition, semiconductor memory device 102 is different from semiconductor memory device 101 in that data signals EXTDQ<0:n> are input into terminal 18, that data signals EXTDQ<0:n> are input into input buffer 11 in place of signals INTADD<0:n>, that data signal EXTDQ<0> is input into high-voltage detection circuit 12 in place of signal INTADD<0>, and that signals DIN<0:n> are input into mode switching circuit 40b in place of signals ADD<0:n>. The other parts are configured as in semiconductor memory device 101 shown in FIG. 1, so that detailed description thereof will not be repeated.

Terminal 18 is a generic representation of a plurality of terminals provided in correspondence to data signals EXTDQ<0:n>, respectively. Terminal 18 receives and outputs data signals EXTDQ<0:n>. Mode switching circuit 40b is activated by a prescribed combination of H and L levels of DIN<1:m>, i.e. at least a part of signals DIN<0:n>, and by signal SVIH of the H level, to change the mode of semiconductor memory device 102 from the normal mode to the test mode.

Output buffer 30 includes a P-channel MOS transistor 21 and an N-channel MOS transistor 25 connected in series between power-supply voltage VCCQ and ground voltage VSS, inverters 22, 23 and 26, and NAND circuits 24 and 27.

NAND circuit 24 performs an NAND logic operation on an output data signal DOUT and a signal OE which is set to the H level at data output. Inverter 23 inverts the output level of NAND circuit 24 for output. Inverter 22 inverts the output level of inverter 23 for output. NAND circuit 27 performs an NAND logic operation on signal OE and a signal /DOUT which is complementary to output data signal DOUT. Inverter 26 inverts the output level of NAND circuit 27 for output.

The gate of P-channel MOS transistor 21 receives the output level of inverter 22. Moreover, a substrate region of P-channel MOS transistor 21 is supplied with power-supply voltage VCCQ. Thus, a parasitic diode occurs between power-supply voltage VCCQ and the connection node of P-channel MOS transistor 21 to N-channel MOS transistor 25. Accordingly, if the voltage of data signal EXTDQ<0> comes to be higher than power-supply voltage VCCQ by at least a predetermined level, P-channel MOS transistor 21 electrically connects power-supply voltage VCCQ to the connection node of P-channel MOS transistor 21 to N-channel MOS transistor 25.

The gate of N-channel MOS transistor 25 receives the output level of inverter 26. Moreover, a substrate region of N-channel MOS transistor 25 is supplied with ground voltage VSS. This causes a parasitic diode between ground voltage VSS and the connection node of P-channel MOS transistor 21 to N-channel MOS transistor 25. Accordingly, when the voltage of data signal EXTDQ<0> comes to be lower than ground voltage VSS by at least a predetermined level, N-channel MOS transistor 25 electrically connects ground voltage VSS to the connection node of P-channel MOS transistor 21 to N-channel MOS transistor 25.

Further, the connection node of P-channel MOS transistor 21 to N-channel MOS transistor 25 outputs data signal EXTDQ<0>. Inverters 22, 23 and 26 in output buffer 30 and NAND circuits 24 and 27 operate with power-supply voltage VCCQ.

An example of operation of semiconductor memory device 102 at data input at the normal mode will now be described. It is assumed that semiconductor memory device 102 operates at a very high frequency and that switching between H and L levels is performed after the voltage of data signal EXTDQ<0> is set to the H or L level and before the voltage becomes constant. Here, by way of example, power-supply voltage VCC is set to 3.3V, ground voltage VSS is OV, the voltage drop level by P-channel MOS transistor 21 and N-channel MOS transistor 25 is 0.6V, and a threshold voltage at which input buffer 11 determines for the H or L level is 1.4V.

It is assumed that data signal EXTDQ<0> is input into semiconductor memory device 102, sequentially having L and H levels, and that the amplitude of data signal EXTDQ<0> is momentarily varied in the range between 1.3V and 5V. This is the phenomenon called overshoot. If no P-channel MOS transistor 21 is provided here, when data signal EXTDQ<0> has 1.3V, data signal EXTDQ<0> that is supposed to be determined as the H level may be determined as the L level by input buffer 11. However, P-channel MOS transistor 21 functions to maintain the voltage of data signal EXTDQ<0> at 3.9V even if it exceeds 3.9V. Thus, data signal EXTDQ<0> will not be determined as the L level by input buffer 11.

It is now assumed that data signal EXTDQ<0> is input into semiconductor memory device 102, sequentially having H and L levels, and that the amplitude thereof is momentarily varied in the range between −2V and 1.5V. This is the phenomenon called undershoot. If no N-channel MOS transistor 25 is provided here, when data signal EXTDQ<0> comes to have 1.5V, data signal EXTDQ<0> that is supposed to be determined as the L level may be determined as the H level by input buffer 11. However, N-channel MOS transistor 25 functions to maintain the voltage of data signal EXTDQ<0> at −0.6V even if it becomes lower than −0.6V. Thus, data signal EXTDQ<0> will not be determined as the H level by input buffer 11.

An example of the operation of semiconductor memory device 102 at data output at the normal mode will now be described. At data output, signal OE is set to the H level. When output data signal DOUT is at the H level, the output level of NAND circuit 24 is the L level. This allows the output level that has passed through inverters 22 and 23 to be the L level. Accordingly, P-channel MOS transistor 21 is turned on, setting data signal EXTDQ<0> to the H level.

As output data signal DOUT is at the H level, a signal /DOUT complementary to output data signal DOUT has the L level. This allows the output level of NAND circuit 27 to be at the H level. Accordingly, the output of inverter 26 has the L level, not turning on N-channel MOS transistor 25.

If output data signal DOUT is at the L level, P-channel MOS transistor 21 is not turned on. Signal /DOUT comes to have the H level, turning P-channel MOS transistor 25 on, thereby setting data signal EXTDQ<0> to the L level.

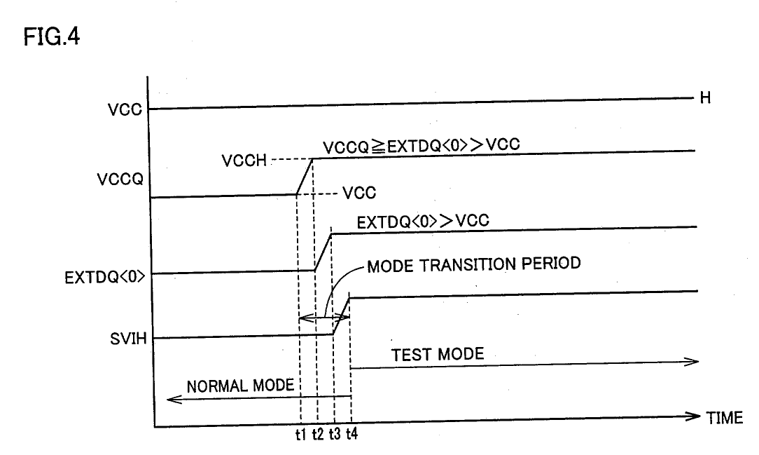

FIG. 4 is an operation waveform illustrating the operation of transition from the normal mode to the test mode in semiconductor memory device 102. The period from time t1 to t4 is a mode transition period for semiconductor memory device 102 to be switched from the normal mode to the test mode. Power-supply voltage VCCQ supplies the same voltage as power-supply voltage VCC before the mode transition period, and supplies voltage VCCH at which the high-voltage detection circuit 12 is activated after time t2 in the mode transition period. Here, by way of example, power-supply voltage VCC is set to 3.3V, ground voltage VSS is 0V, the voltage level at which high-voltage detection circuit 12 is activated is 5V, the voltage drop level by P-channel MOS transistor 21 and N-channel MOS transistor 25 is 0.6V, and voltage VCCH is 5V.

Referring to FIGS. 3 and 4, in semiconductor memory device 102, power-supply voltage VCCQ supplies voltage VCCH at time t2. Subsequently, at time t3, terminal 18 receives an input of data signal EXTDQ<0> of 5V for transition to the test mode.

High-voltage detection circuit 12 is activated when data signal EXTDQ<0> of 5V is input, setting output signal SVIH to the H level. If data signals EXTDQ<1:m> of data signals EXTDQ<0:n> are input to terminal 18 with a prescribed combination of H and L levels, signals DIN<1:m> also have the prescribed combination of H and L levels, activating mode switching circuit 40b. As a result, at mode t4, mode switching circuit 40b changes the mode of semiconductor memory device 102 from the normal mode to the test mode.

In semiconductor memory device 102, after transition to the test mode, it is assumed that data signal EXTDQ<0> to be input is set to 5V at the H level and 0V at the L level. By contrast, data signal EXTDQ<0> at the normal mode is set to 3.3V at the H level and 0V at the L level. Thus, the time during which semiconductor memory device 102 reads out data in the order of H and L levels and data signal EXTDQ<0> is determined as the L level by an external circuit (not shown) connected to terminal 18 becomes longer than that at the normal mode. Specifically, the time required for data signal EXTDQ<0> to be determined as the L level corresponds to the time required for data signal EXTDQ<0> to be changed in voltage from 3.3V to 1.4V at the normal mode, whereas it corresponds to the time required for data signal EXTDQ<0> to be changed in voltage from 5V to 1.4V at the test mode. On the contrary, when semiconductor memory device 102 reads out data in the order of L and H, the time required for data reading in the normal mode and in the test mode are almost the same, corresponding to the time required for data signal EXTDQ<0> to be changed in voltage from 0V to 1.4V. Hence, only when data is read in the order of H and L levels, semiconductor memory device 102 has a disadvantage in that the time for data reading is longer in the test mode than in the normal mode.

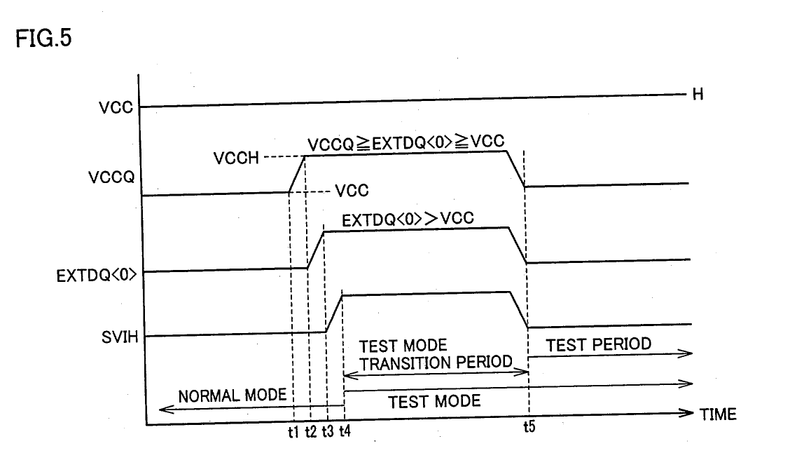

FIG. 5 is an operation waveform illustrating the operation at transition from the normal mode to the test mode in semiconductor memory device 102 when power-supply voltage VCCQ in output buffer 30 is lowered to VCC after transition to the test mode. The period from time t4 to t5 is a test mode transition period after semiconductor memory device 102 is switched to the test mode and before a multi-bit test or the like is performed. The period after time t5 is a test period during which the multi-bit test or the like is actually performed in semiconductor memory device 102. Here, by way of example, power-supply voltage VCC is set to 3.3V, ground voltage VSS is 0V, the voltage level at which high-voltage detection circuit 12 is activated is 5V, and the voltage drop level by P-channel MOS transistor 21, and N-channel MOS transistor 25 is 0.6V.

Referring to FIGS. 3 and 5, at time t1, t2, t3 and t4, semiconductor memory device 102 operates as in the case shown in FIG. 4, so that detailed description thereof will not be repeated.

At time t5, power-supply voltage VCCQ in output buffer 30 is the same as that in the normal mode, i.e. VCC (3.3V). Accordingly, if power-supply voltage VCCQ comes to be VCC, the voltage of signal EXTDQ<0> at the H level is set to 3.3V. This results that the time required for data reading can be the same as in the normal mode in semiconductor memory device 102, even if data is read out in the order of H and L levels after transition to the test mode.

As described above, at the normal mode, semiconductor memory device 102 can prevent overshoot and undershoot of the input signal by P-channel MOS transistor 21 and N-channel MOS transistor 25 in output buffer 30. More specifically, P-channel MOS transistor 21 and N-channel MOS transistor 25 function as a clamp circuit. This can eliminate the need for provision of diodes 13 and 14 at each terminal as in semiconductor memory device 101, thereby reducing the circuit area and cost. Moreover, semiconductor memory device 102 can normally perform transition to the test mode. Furthermore, in semiconductor memory device 102, time required for data reading at the test mode can be the same as that at the normal mode by lowering power-supply voltage VCCQ to VCC after transition to the test mode.

Third Embodiment

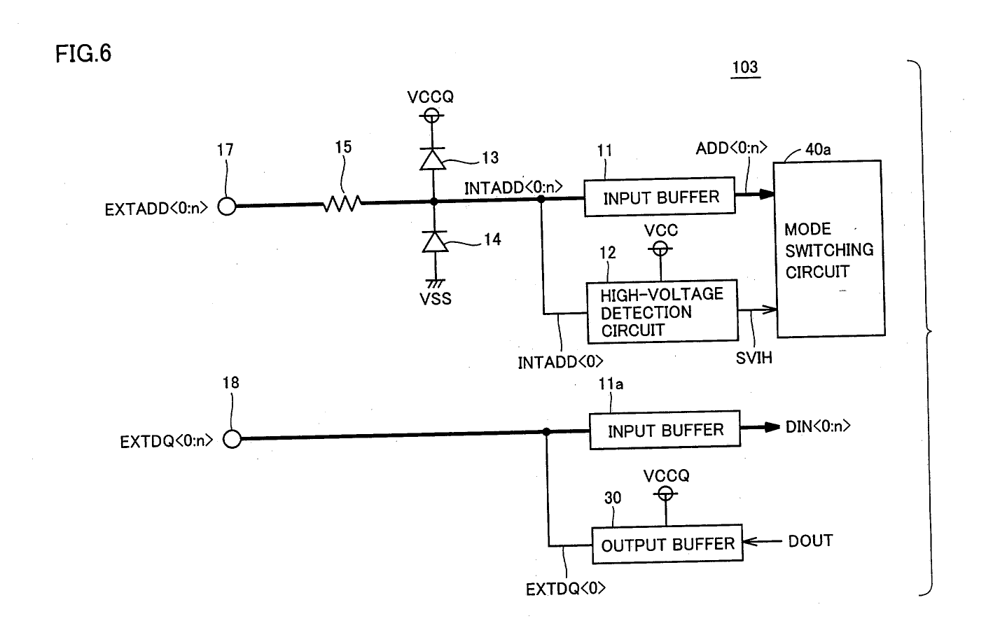

Referring to FIG. 6, a semiconductor memory device 103 according to the third embodiment of the present invention is different from semiconductor memory device 101 shown in FIG. 1 in that it further includes a terminal 18, an input buffer 11a and an output buffer 30. The other parts are configured as in semiconductor memory device 101 shown in FIG. 1, so that detailed description thereof will not be repeated.

Input buffer 11a is a generic representation of a plurality of input buffers provided in correspondence to data signals EXTDQ<0:n>, respectively. Further, input buffer 11a has a function similar to that of input buffer 11.

The operation of semiconductor memory device 103 for switching the operation mode from the normal mode to the test mode and that for preventing overshoot and undershoot at the normal mode are similar to those in semiconductor memory device 101, so that detailed description thereof will not be repeated.

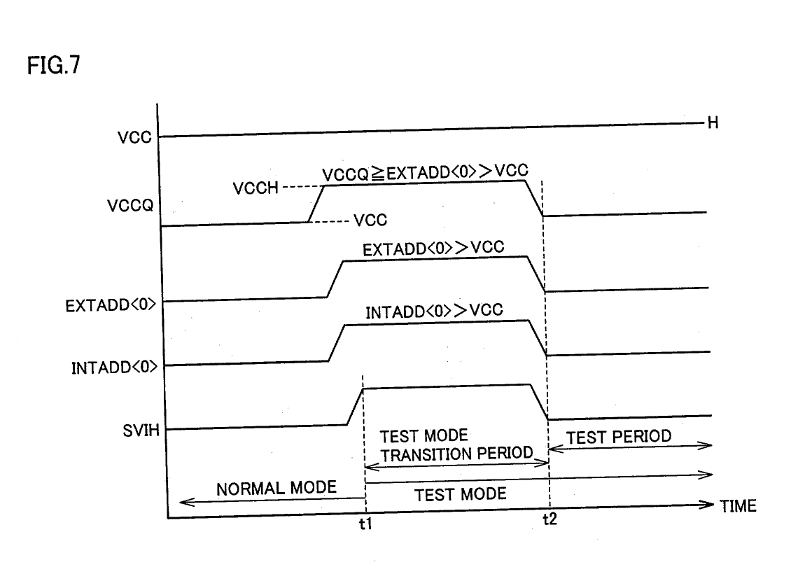

FIG. 7 is an operation waveform illustrating the operation of semiconductor memory device 103 at transition from the normal mode to the test mode when power-supply voltage VCCQ supplied to output buffer 30 is lowered to VCC after transition to the test mode. The period from time t1 to t2 is a test mode transition period after semiconductor memory device 103 is switched to the test mode and before a multi-bit test or the like is performed. The period after time t2 is a test period during which the multi-bit test or the like is actually performed in semiconductor memory device 103. Here, by way of example, power-supply voltage VCC is set to 3.3V and ground voltage VSS is set to 0V.

When power-supply voltage VCCQ supplied to output buffer 30 comes to be VCC at time t2, the voltage of signal EXTDQ<0> at the H level is set to be the same as that in the normal mode, i.e. 3.3V, as in semiconductor memory device 102. Therefore, as described in the second embodiment, semiconductor memory device 103 can have the same time required for data reading in the test mode as that in the normal mode.

Accordingly, semiconductor memory device 103 can prevent overshoot and undershoot of an input signal in the normal mode, while normally performing transition operation to the test mode, as in semiconductor memory device 101.

In addition, the time required for data reading at the test mode can be the same as that in the normal mode by lowering power-supply voltage VCCQ to VCC after transition to the test mode.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device having a normal mode and a test mode as operation modes, comprising:
a plurality of terminals capable of receiving inputs of external voltage signals;
a high-voltage detection circuit supplied with an operation voltage from a first power-supply node and detecting that a first prescribed voltage higher than a voltage of said first power-supply node is applied to one terminal of said plurality of terminals to produce an instruction for mode transition;
a first clamp circuit provided between a second power-supply node and said one terminal and electrically connecting said one terminal to said second power-supply node if a voltage of said one terminal is lower than a voltage of said second power-supply node by a prescribed level;
a second clamp circuit provided between a third power-supply node and said one terminal and electrically connecting said one terminal to said third power-supply node if the voltage of said one terminal is higher than a voltage of said third power-supply node by a prescribed level; and
a mode switching circuit changing the operation mode from said normal mode to said test mode in response to a combination of voltage levels of at least a part of said plurality of terminals and to said instruction for mode transition,
said first and third power-supply nodes having voltages higher than the voltage of said second power-supply node,
said first and third power-supply nodes being supplied with a voltage of almost a same level at said normal mode,
said third power-supply node being supplied with a voltage higher than the voltage of said first power-supply node corresponding to said first prescribed voltage at transition to said test mode.

2. The semiconductor memory device according to claim 1, wherein said voltage signals are address signals.

3. The semiconductor memory device according to claim 1, further comprising a data output circuit,
said data output circuit being supplied with an operation voltage from said third power-supply node,
said third power-supply node being supplied with a voltage substantially equal to the voltage of said first power-supply node after transition to said test mode.

4. A semiconductor memory device having a normal mode and a test mode as operation modes, comprising:
a plurality of terminals capable of receiving inputs of external voltage signals;
a high-voltage detection circuit supplied with an operation voltage from a first power-supply node and producing an instruction for mode transition in response to a first prescribed voltage higher than a voltage of said first power-supply node being applied to one terminal of said plurality of terminals;
a mode switching circuit changing the operation mode from said normal mode to said test mode in response to a combination of voltage levels of at least a part of said plurality of terminals and to said instruction for mode transition;
a data line connected to said one terminal; and
a data output circuit sending output data to said data line,
said data output circuit including first and second transistors provided between said data line and second and third power-supply nodes respectively and complementarily turned on at data output in accordance with said output data,
substrate regions of said first and second transistors being electrically connected to said second and third power-supply nodes respectively,
said first and second power-supply nodes having voltages higher than a voltage of said third power-supply node,
said first and second power-supply nodes being supplied with a voltage of almost a same level at said normal mode,
said second power-supply node being supplied with a voltage higher than the voltage of said first power-supply node corresponding to said first prescribed voltage at transition to said test mode.

5. The semiconductor memory device according to claim 4, wherein said voltage signals are data signals.

6. The semiconductor memory device according to claim 4, wherein said second power-supply node is supplied with a voltage substantially equal to the voltage of said first power-supply node in said data output circuit, after transition to said test mode.
